(19) United States
(12) Patent Application Publication
(10) Pub. No.: US 2023/0352542 A1
(43) Pub. Date: Nov. 2, 2023

(54) MULTI-TERMINAL GALLIUM NITRIDE POWER TRANSISTOR

(71) Applicant: HUAWEI TECHNOLOGIES CO., LTD., Shenzhen (CN)

(72) Inventor: Gilberto CURATOLA, Nuremberg (DE)

(21) Appl. No.: 18/349,267

(22) Filed: Jul. 10, 2023

Related U.S. Application Data
(63) Continuation of application No. PCT/EP2021/050385, filed on Jan. 11, 2021.

(51) Int. Cl. H01L 29/20; H01L 29/417; H01L 29/06; H02M 3/158

(52) U.S. Cl. CPC H01L 29/2003; H01L 29/41758; H01L 29/0696; H02M 3/158

(57) ABSTRACT

The present disclosure relates to a Gallium Nitride (GaN) power transistor. The GaN power transistor includes a source pad, a drain pad, a first and a second gate pad, a plurality of unit cells where each unit cell includes a source region, a drain region and a gate region. The power transitory further includes a source metallization layer contacting the source regions of the plurality of unit cells with the source pad, a drain metallization layer contacting the drain regions of the plurality of unit cells with the drain pad, a first gate metallization layer contacting the gate region of a first portion of the unit cells with the first gate pad, and a second gate metallization layer contacting the gate region of a second portion of the unit cells with the second gate pad.

### CROSS-REFERENCE TO RELATED APPLICATIONS

This application is a continuation of International Application No. PCT/EP2021/050385, filed on Jan. 11, 2021, which is hereby incorporated by reference in its entirety.

### TECHNICAL FIELD

The present disclosure relates to the field of Gallium Nitride (GaN) technology for power device applications. In particular, the present disclosure relates to a multi-terminal GaN power transistor in split-gate GaN technology for highest efficiency power converters.

### BACKGROUND

Although the efficiency of power supplies has improved significantly in the last decade, most efforts still focus on improving efficiency at medium to heavy loads. However, light-load efficiency is becoming more and more important. For example, the 80-Plus Titanium efficiency standards not only requires 96% efficiency at a 50% load, but 90% efficiency at a 10% load and 94% efficiency at a 20% load. The efficiency of a power converter can be described as a function of the load current. It has shown that at light load conditions, the efficiency is strongly compromised with respect to peak load conditions.

### SUMMARY

It is the object of this disclosure to provide a new device concept for a GaN power transistor that allows to largely improve the efficiency of power converters, especially at light load conditions.

This object is achieved by the features of the independent claims. Further implementation forms are apparent from the dependent claims, the description and the figures.

A basic idea of this disclosure is to provide a configurable multi-terminal GaN device whose size, and therefore figures of merit (FOM)s, can be tuned during device operation thanks to its inherent lateral nature. A configurable GaN layout with multiple terminals is further provided that allows, depending on the converter operation (light-load or heavy-load), to modify the die area and consequently performance and achieve constant highest efficiency possible. The device performance (QG, QGD, QOSS, RDSON) can be electrically tuned during device operation.

The disclosure is based on the finding that design of power converters is mostly a trade-off between efficiency and power density. While power density is mainly driven by the passive elements and heatsink volume, the efficiency is mainly impacted by the semiconductor losses (conduction and switching). A simple losses breakdown can be performed as follows:
Conduction losses: R*I²*D,
Gate Driving losses: Q_{G}*V_{G}*f
Output capacitive losses: C_{OSS}*V_{DS}²*f
Crossover losses: I_{ON}*V_{DS}*dt,
   where D represents the converter duty cycle, Q_{g} the gate charge, Cₒₛₛ represents the output capacitance, f represents the operation frequency and dt, finally, represents the time during which the transistor experiences, at the same time, high current and high voltage.

The converter efficiency depends on both, the input voltage and the transistor size. In the example of a DC-DC buck converter for battery charger applications, when the battery is discharged, the buck switch should be turned on for a longer period of time in order to maintain the output voltage at the desired level. In these conditions, therefore, it is beneficial to have a transistor with low on-state resistance in order to minimize the conduction losses. On the other side, when the battery is fully charged, it is the device output capacitance that plays a more important role in determining the overall converter efficiency.

From the above considerations, it has shown that a semiconductor device with different figure of merits depending on the status of the converter and its load conditions is desirable. The possibility to tune the device figure of merits dynamically during operation allows to always operate the converter in maximum efficiency conditions.

Based on the above findings, the present disclosure provides a new semiconductor device whose performance can be electrically tuned during device operation. Although the semiconductor device is exemplarily presented hereinafter for a GaN semiconductor device, it understands that the basic concept can be applied to other semiconductor techniques as well.

In order to describe the technology in detail, the following terms, abbreviations and notations will be used:
GaN Gallium-Nitride
FET Field Effect Transistor
pGaN p-doped GaN
AlGaN Aluminum Gallium-Nitride
2DEG 2-dimensional electron gas
HV high voltage (operation), e.g. >600 V
MV medium voltage (operation), e.g. 200-600 V
V_{TH} threshold voltage
S source or source pad
D drain or drain pad
G gate or gate pad

According to a first aspect, the disclosure relates to a Gallium Nitride (GaN) power transistor comprising: a source pad; a drain pad; a first and a second gate pad; a plurality of unit cells each unit cell comprising a source region, a drain region and a gate region; a source metallization layer contacting the source regions of the plurality of unit cells with the source pad; a drain metallization layer contacting the drain regions of the plurality of unit cells with the drain pad; a first gate metallization layer contacting the gate region of a first portion of the unit cells with the first gate pad; and a second gate metallization layer contacting the gate region of a second portion of the unit cells with the second gate pad.

Such a GaN power transistor introduces a new device that may be used in power converters allowing to largely improve their efficiency, especially at light load conditions. The transistor provides a configurable multi-terminal GaN device whose size, and therefore FOMs (figures of merit), can be tuned during device operation thanks to its inherent lateral nature. The configurable layout with multiple terminals allows, depending on the converter operation (light-load or heavy-load), to modify the die area and consequently performance and achieve constant highest efficiency. The device performance can be electrically tuned during device operation.

In an exemplary implementation of the GaN power transistor, the first portion of the unit cells and the second portion of the unit cells have a ratio of N in terms of area.

This provides the advantage that device operation and device performance can be tuned during device operation.

In an exemplary implementation of the GaN power transistor, the source pad forms a common source terminal of the GaN power transistor for all unit cells; wherein the drain pad forms a common drain terminal of the GaN power transistor for all unit cells; wherein the first gate pad forms a first gate terminal of the GaN power transistor for the first portion of the unit cells; and wherein the second gate pad forms a second gate terminal of the GaN power transistor for the second portion of the unit cells.

This corresponds to a first example of the GaN power transistor as described below with respect to FIGS. 1, 2a and 2b.

This provides the advantage that by separation of the gate into two parts, two different sets of gate fingers can be selected from different portion of the overall device layout.

In an exemplary implementation of the GaN power transistor, an input capacitance N*CGS between the second gate terminal and the source terminal is N times larger than an input capacitance CGS between the first gate terminal and the source terminal; and wherein an input capacitance N*CGD between the second gate terminal and the drain terminal is N times larger than an input capacitance CGD between the first gate terminal and the drain terminal.

This corresponds to the first example of the GaN power transistor as described below with respect to FIGS. 1, 2a and 2b.

This provides the advantage that input capacitances of the device can be flexible set during device operation.

In an exemplary implementation of the GaN power transistor, an output capacitance of the GaN power transistor is N+1 times a capacitance CDS between the drain terminal and the source terminal.

This corresponds to the first example of the GaN power transistor as described below with respect to FIGS. 1, 2a and 2b.

This provides the advantage that output capacitances of the device can be flexible set during device operation.

In an exemplary implementation of the GaN power transistor, input capacitances of the GaN power transistor can be modified during operation by selecting one or both of the first and second gate terminals.

This corresponds to the first example of the GaN power transistor as described below with respect to FIGS. 1, 2a and 2b.

This provides the advantage that input capacitances of the device can be modified during device operation by setting the respective gate terminals. Thus, different figure of merits can be realized.

In an exemplary implementation of the GaN power transistor, a first device capacitance configuration: (N+1)*CGS, (N+1)*CGD, (N+1)*CDS can be set by enabling both gate terminals; wherein a second device capacitance configuration: CGS, CGD, (N+1)*CDS can be set by enabling the first gate terminal and disabling the second gate terminal; and wherein a third device capacitance configuration: N*CGS, N*CGD, (N+1)*CDS can be set by disabling the first gate terminal and enabling the second gate terminal.

This corresponds to the first example of the GaN power transistor as described below with respect to FIGS. 1, 2a and 2b.

This provides the advantage that input capacitances of the device can be flexible switched during device operation between different configurations.

In an exemplary implementation of the GaN power transistor, the source pad is separated in a first source pad and a second source pad; wherein the drain pad is separated in a first drain pad and a second drain pad; wherein the source metallization layer is separated in a first source metallization layer contacting the source regions of the first portion of the unit cells with the first source pad and a second source metallization layer contacting the source regions of the second portion of the unit cells with the second source pad; and wherein the drain metallization layer is separated in a first drain metallization layer contacting the drain regions of the first portion of the unit cells with the first drain pad and a second drain metallization layer contacting the drain regions of the second portion of the unit cells with the second drain pad.

This corresponds to a second example of the GaN power transistor as described below with respect to FIGS. 3, 4a and 4b.

Such a GaN power transistor design can be applied for low/medium voltages as well as for high voltages. The design provides the following advantages: Multiple gate, source and drain terminals; Device figure of merits (FOMs) can be electrically tuned during device operation by selecting the appropriate gate, source and drain terminals.

In an exemplary implementation of the GaN power transistor, the first source pad forms a first source terminal of the GaN power transistor for the first portion of the unit cells; wherein the second source pad forms a second source terminal of the GaN power transistor for the second portion of the unit cells; wherein the first drain pad forms a first drain terminal of the GaN power transistor for the first portion of the unit cells; and wherein the second drain pad forms a second drain terminal of the GaN power transistor for the second portion of the unit cells.

This corresponds to the second example of the GaN power transistor as described below with respect to FIGS. 3, 4a and 4b.

This provides the advantage that by separation of the gate, source and drain into two parts, respectively, gate, source and drain can connect different portions of the overall device.

In an exemplary implementation of the GaN power transistor, an input capacitance N*CGS between the second gate terminal and the second source terminal is N times larger than an input capacitance CGS between the first gate terminal and the first source terminal; and wherein an input capacitance N*CGD between the second gate terminal and the second drain terminal is N times larger than an input capacitance CGD between the first gate terminal and the first drain terminal.

This corresponds to the second example of the GaN power transistor as described below with respect to FIGS. 3, 4a and 4b.

This provides the advantage that input capacitances of the device can be flexible set during device operation.

In an exemplary implementation of the GaN power transistor, device capacitances of the GaN power transistor can be modified during operation by selecting one or both of the first and second gate terminals.

This corresponds to the second example of the GaN power transistor as described below with respect to FIGS. 3, 4a and 4b.

This provides the advantage that input capacitances of the device can be modified during device operation by setting the respective gate terminals. Thus, different figure of merits can be realized.

In an exemplary implementation of the GaN power transistor, a first device capacitance configuration: (N+1)*C_{GS}, (N+1)*C_{GD}, (N+1)*C_{DS} can be set by enabling both gate terminals; wherein a second device capacitance configuration: C_{GS}, C_{GD}, C_{DS} can be set by enabling the first gate terminal and disabling the second gate terminal; and wherein a third device capacitance configuration: N*C_{GS}, N*C_{GD}, N*C_{DS} can be set by disabling the first gate terminal and enabling the second gate terminal.

This corresponds to the second example of the GaN power transistor as described below with respect to FIGS. 3, 4a and 4b.

This provides the advantage that input capacitances of the device can be flexible switched during device operation between different configurations.

In an exemplary implementation of the GaN power transistor, the source pad is separated in multiple source pads; wherein the drain pad is separated in multiple drain pads; wherein the first and the second gate pad are separated in multiple gate pads; wherein the source metallization layer is separated in multiple source metallization layers, each source metallization layer contacting the source region of a respective portion of the unit cells with a respective source pad of the multiple source pads; wherein the drain metallization layer is separated in multiple drain metallization layers, each drain metallization layer contacting the drain region of a respective portion of the unit cells with a respective drain pad of the multiple drain pads; and wherein the gate metallization layer is separated in multiple gate metallization layers, each gate metallization layer contacting the gate region of a respective portion of the unit cells with a respective gate pad of the multiple gate pads.

This corresponds to a third example of the GaN power transistor as described below with respect to FIGS. 5 and 7.

Such a GaN power transistor design can be applied for low/medium voltages as well as for high voltages. The design provides the advantages of multiple gate, source and drain terminals and device figure of merits (FOMs) that can be electrically tuned during device operation by selecting the appropriate gate, source and drain terminals.

In an exemplary implementation of the GaN power transistor, the respective portions of the unit cells have different ratios in terms of area.

This corresponds to the third example of the GaN power transistor as described below with respect to FIGS. 5 and 7.

This provides the advantage that different device configurations with respect to different areas of the device can be selected.

In an exemplary implementation of the GaN power transistor, each unit cell comprises: a buffer layer; a barrier layer deposited on the buffer layer; and a p-type doped GaN layer deposited on top of the barrier layer, wherein the gate region of the unit cell is formed on top of the p-type doped GaN layer; and wherein the source region and the drain region of the unit cell are formed laterally to the barrier layer.

Such a GaN power transistor allows optimum operation with stable threshold voltage, suppression of dynamic instabilities and improved gate reliability in normally-off operation.

In an exemplary implementation of the GaN power transistor, each unit cell comprises: a buffer layer; a barrier layer deposited on the buffer layer; and a passivation layer deposited on top of the barrier layer, wherein the gate region of the unit cell is formed on top of the passivation layer; and wherein the source region and the drain region of the unit cell are formed laterally to the barrier layer.

Such a GaN power transistor allows optimum operation with stable threshold voltage, suppression of dynamic instabilities and improved gate reliability in normally-on operation.

In an exemplary implementation of the GaN power transistor, the buffer layer comprises a GaN layer or an Aluminum Gallium Nitride (AlGaN) layer.

A buffer layer comprising GaN or AlGaN improves electron mobility of the transistor. The buffer layer further reduces reverse leakage currents in the transistor and improves on-off ratios of the transistor.

In an exemplary implementation of the GaN power transistor, the barrier layer comprises an AlGaN layer.

A transistor with such a barrier layer shows improved radio frequency (RF) characteristics and direct current (DC) performance.

In an exemplary implementation of the GaN power transistor, the buffer layer is formed on at least one transition layer that is formed on a Silicon substrate.

Such a power transistor provides improved gate leakage current decrease.

In an exemplary implementation of the GaN power transistor, the source metallization layer comprises at least one crossing with the drain metallization layer in order to connect the source regions of the plurality of unit cells with the source pad; and wherein the drain metallization layer comprises at least one crossing with the source metallization layer in order to connect the drain regions of the plurality of unit cells with the drain pad.

Such a GaN power transistor provides flexible design options as the crossings of the source metallization layer with the drain metallization layer can be used to guide the source metallization layer (and the drain metallization layer) to different areas of the device.

In an exemplary implementation of the GaN power transistor, the source pad and the drain pad are arranged on top of an active area of the GaN power transistor formed by the plurality of unit cells. This allows a flexible and space-efficient design.

This is the medium-voltage GaN power device layout. In the medium-voltage layout, there is a crossing of the source and drain metal layers in order to connect the different fingers. This has two main implications: firstly, the source and drain pads are on top of the active area (bond over active); secondly, the inter-level passivation layers must be capable of withstanding the all rated voltage for the device in question (i.e. 600V for a 600-rated metal-oxide-semiconductor field-effect transistor (MOSFET)).

The metal crossing does not have to be aligned in different orientation. Different metal layers may be stacked on top of each other (by passivation layers). In the medium voltage layout, the metal layers are separated by passivation layers. These passivation layers have to withstand the full voltage.

In an exemplary implementation of the GaN power transistor, the source pad and the drain pad are arranged outside of an active area of the GaN power transistor formed by the plurality of unit cells.

This provides the advantage that higher voltages can be applied when there is no need for crossings and corresponding thick passivation layers that withstand these high voltages.

In an exemplary implementation of the GaN power transistor, the source metallization layer is arranged side by side with the drain metallization layer in order to connect the source regions of the plurality of unit cells with the source pad; and wherein the drain metallization layer is arranged side by side with the source metallization layer in order to connect the drain regions of the plurality of unit cells with the drain pad.

Source metallization layer and drain metallization layer are arranged side by side. This means, there are no crossings between both layers. This provides the advantage that the design withstands high voltages, e.g. higher than 600V.

A further aspect of the disclosure relates to fabrication of a multiple terminals GaN power MOSFET whose FOMS can be electrically tuned during device operation. In particular, the different device terminals connect portion of the GaN device with different area and, therefore, different on-state resistance and capacitances. Those terminals can be alternatively selected during device operation in such a way to select the needed on-state resistance and/or device capacitance.

### BRIEF DESCRIPTION OF THE DRAWINGS

Further embodiments of the technology will be described with respect to the following figures, in which:

FIG. 1 shows an exemplary medium-voltage layout example of the new GaN power transistor according to a first example;

FIG. 2a shows a transistor symbol of the new GaN power transistor according to the first example;

FIG. 2b shows a circuit diagram illustrating an equivalent circuit of the new GaN power transistor according to the first example;

FIG. 3 shows an exemplary medium-voltage layout example of the new GaN power transistor according to a second example;

FIG. 4a shows a transistor symbol of the new GaN power transistor according to the second example;

FIG. 4b shows a circuit diagram illustrating an equivalent circuit of the new GaN power transistor according to the second example;

FIG. 5 shows an exemplary medium-voltage layout example of the new GaN power transistor according to a third example;

FIG. 6 shows an exemplary high-voltage layout example of the new GaN power transistor according to the disclosure;

FIG. 7 shows an example schematic diagram of a multi-terminal GaN power device according to the disclosure; and

FIG. 8 shows a schematic diagram illustrating an exemplary structure of the new GaN power transistor according to the disclosure.

### DETAILED DESCRIPTION OF EMBODIMENTS

In the following detailed description, reference is made to the accompanying drawings, which form a part thereof, and in which is shown by way of illustration specific aspects in which the disclosure may be practiced. It is understood that other aspects may be utilized and structural or logical changes may be made without departing from the scope of the present disclosure. The following detailed description, therefore, is not to be taken in a limiting sense, and the scope of the present disclosure is defined by the appended claims.

It is understood that comments made in connection with a described device may also hold true for a corresponding method configured to implement the device and vice versa. For example, if a specific unit of a device is described, a corresponding method may include a method step to perform the functionality of the described unit, even if such a method step is not explicitly described or illustrated in the figures. Further, it is understood that the features of the various exemplary aspects described herein may be combined with each other, unless specifically noted otherwise.

The semiconductor power transistors and devices described herein may be implemented inter alia in wireless communication schemes, in particular communication schemes according to 5th generation (5G) (although any other communication schemes also applicable). The described power transistors and devices may be used to produce integrated circuits and/or electronic circuits and may be manufactured according to various technologies. For example, the power transistors and semiconductor devices may be utilized in logic integrated circuits, analog integrated circuits, mixed signal integrated circuits, optical circuits, memory circuits and/or integrated passives.

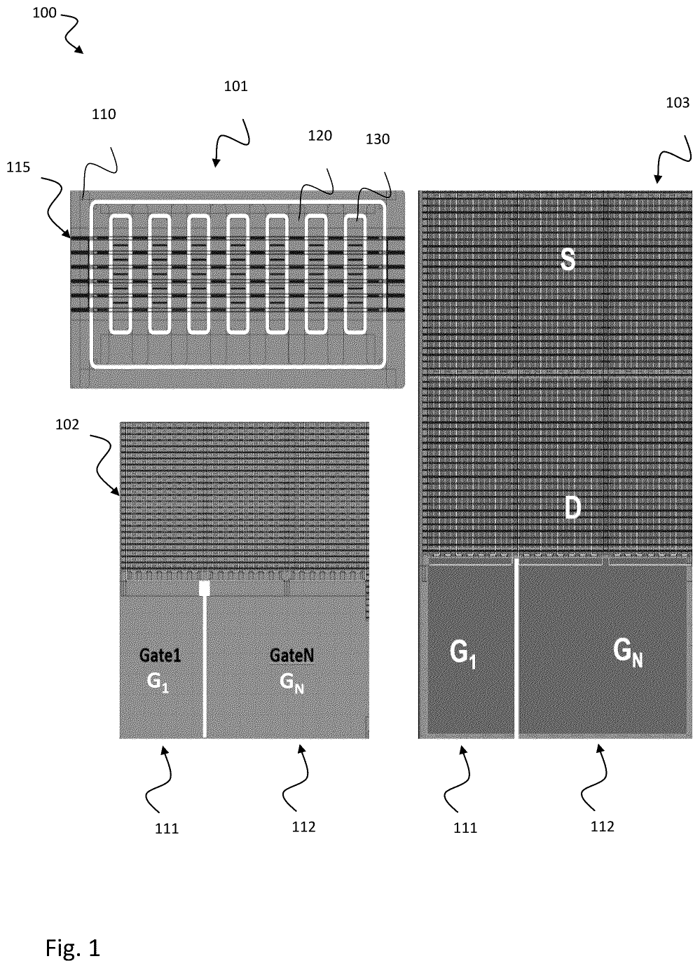

FIG. 1 shows an exemplary medium-voltage layout example 100 of the new GaN power transistor according to a first example.

Such a layout is utilized for medium-voltage GaN power devices, i.e. with medium voltages smaller than about 200V. Highlighted in the picture are the gate, source and drain fingers which are connected to different metal layers by means of via connections. In the upper left part of FIG. 1 is shown an elementary cell 101 of the overall layout, where it is visualized how the drain fingers 115 are connected to multiple metal layers that are fully surrounded by a source metal 120 and then surrounded by a gate metal 110. This elementary cell 101 is repeated over and over, depending on the total number of fingers 115 and, therefore, on the device area. In the right part of FIG. 1 is shown a top view 103 of the design where the final gate, drain and source power metals connect through several vias, the different elementary cells 101 shown in the upper left part of FIG. 1.

The gate pad has been split in two parts, G1 (111) and GN (112), which collect two different sets of gate fingers 115 from different portion of the overall device layout. In particular, Gate1 and GateN represent the outer terminals of two parts of the device that have a ratio on N in terms of area. Source and Drain are common.

In the lower left part of FIG. 1 is shown a top view 102 of a rectangular design where the Gate1 and GateN parts 111, 112 are arranged at a long edge of the rectangular design while in the top view 103 of the right part of FIG. 1, the Gate1 and GateN parts 111, 112 are arranged at the short edge of the rectangular design.

Such a GaN power transistor 100 comprises a source pad S; a drain pad D; a first and a second gate pad G1, GN; a plurality of unit cells 101 each unit cell comprising a source region 120, a drain region 130 and a gate region 110; a source metallization layer contacting the source regions 120 of the plurality of unit cells 101 with the source pad S; a drain metallization layer 115 contacting the drain regions 130 of the plurality of unit cells 101 with the drain pad D; a first gate metallization layer contacting the gate region 110 of a first portion of the unit cells 101 with the first gate pad G1; and a second gate metallization layer contacting the gate region 110 of a second portion of the unit cells 101 with the second gate pad GN.

The first portion of the unit cells 101 and the second portion of the unit cells 101 may have a ratio of N in terms of area.

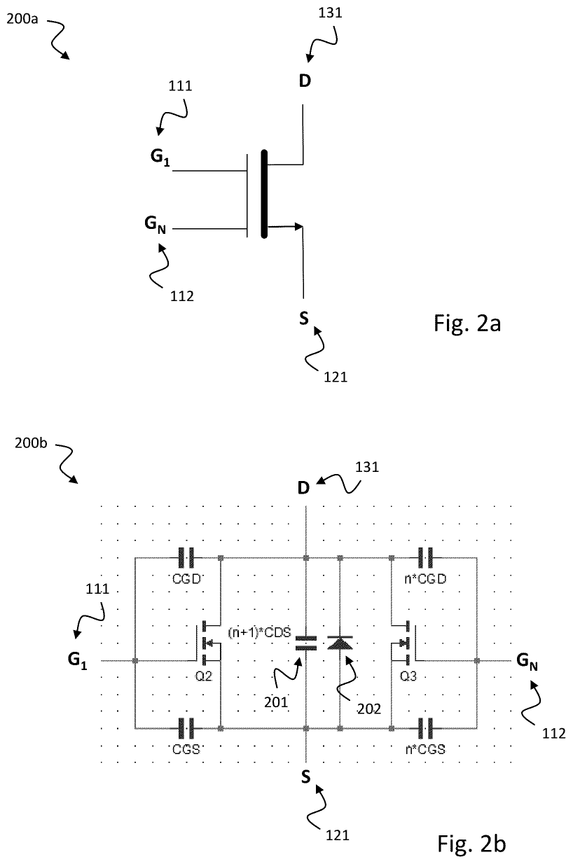

The source pad S may form a common source terminal 121 of the GaN power transistor 100 for all unit cells 101; and the drain pad D may form a common drain terminal 131 of the GaN power transistor 100 for all unit cells 101. The first gate pad G1 may form a first gate terminal 111 of the GaN power transistor 100 for the first portion of the unit cells 101; and the second gate pad GN may form a second gate terminal 112 of the GaN power transistor 100 for the second portion of the unit cells 101, see also FIG. 2b described below.

An input capacitance N*CGS between the second gate terminal 112, GN and the source terminal 121, S may be N times larger than an input capacitance CGS between the first gate terminal 111, G1 and the source terminal 121, S, e.g. as described below with respect to FIG. 2b. An input capacitance N*CGD between the second gate terminal 112, GN and the drain terminal 131, D may be N times larger than an input capacitance CGD between the first gate terminal 111, G1 and the drain terminal 131, D, e.g. as described below with respect to FIG. 2b.

An output capacitance of the GaN power transistor 100 may be N+1 times a capacitance CDS between the drain terminal 131, D and the source terminal 121, S, e.g. as described below with respect to FIG. 2b.

Input capacitances of the GaN power transistor 100 can be modified during operation by selecting one or both of the first 111, G₁ and second 112, G_{N} gate terminals.

A first device capacitance configuration: (N+1)*C_{GS}, (N+1)*C_{GD}, (N+1)*C_{DS} can be set by enabling both gate terminals (111, G₁, 112, G_{N}). A second device capacitance configuration: C_{GS}, C_{GD}, (N+1)*C_{DS} can be set by enabling the first gate terminal 111, G₁ and disabling the second gate terminal 112, G_{N}. A third device capacitance configuration: N*C_{GS}, N*C_{GD}, (N+1)*C_{DS} can be set by disabling the first gate terminal 111, G₁ and enabling the second gate terminal 112, G_{N}, e.g. as described below with respect to FIG. 2b.

The source metallization layer may comprise at least one crossing with the drain metallization layer in order to connect the source regions 120 of the plurality of unit cells 101 with the source pad S. The drain metallization layer may comprise at least one crossing with the source metallization layer in order to connect the drain regions 130 of the plurality of unit cells 101 with the drain pad D.

The source pad S and the drain pad D may be arranged on top of an active area of the GaN power transistor formed by the plurality of unit cells 101.

This is the medium-voltage GaN power device layout 100. In the medium-voltage layout, there is a crossing of the source and drain metal layers in order to connect the different fingers. This has two main implications: firstly, the source and drain pads are on top of the active area (bond over active); secondly, the inter-level passivation layers must be capable of withstanding the all rated voltage for the device in question (i.e. 600V for a 600-rated MOSFET).

The metal crossing does not have to be aligned in different orientation. Different metal layers may be stacked on top of each other (by passivation layers). In the medium voltage layout, the metal layers are separated by passivation layers. These passivation layers have to withstand the full voltage.

FIGS. 2a and 2b show the symbol and equivalent circuit of the GaN power transistor, where the different device capacitance CGS, CGD and CDS are highlighted.

FIG. 2a shows a transistor symbol 200a of the new GaN power transistor according to the first example. The transistor can be represented by a four terminals device, where S represent the common source terminal 121, D represents the common drain terminal 131, and G1 and GN represent, respectively, the two gate terminals 111, 112.

FIG. 2b shows a circuit diagram 200b illustrating an equivalent circuit of the new GaN power transistor according to the first example. The two gate terminals 111, 112 connect the two portions of the device that have an area ratio of N. This means that the input capacitances seen from gate terminal 1 are CGS and CGD, while the input capacitances seen from second gate terminal are N-times larger, i.e. N*CGS and N*CGD. Due to the fact that source and drain terminals 121, 131 are, instead, in common, the output capacitance is (N+1)*CDS.

In the circuit diagram 200b, the first gate terminal 111 is connected via capacitance CGD with drain terminal 131 and via capacitance CGS with source terminal 121. The second gate terminal 112 is connected via capacitance N*CGD with drain terminal 131 and via capacitance N*CGS with source terminal 121. Source terminal 121 is connected via parallel connection of transistor Q2, transistor Q3, capacitance 201 and diode 202 to drain terminal 131.

By selecting one or both gate terminals 111, 112, the following configuration of device capacitances can be obtained:
V_{G1} ON, V_{GN} ON→(n+1)*C_{GS}, (n+1)*C_{GD}, (n+1)*C_{DS}
V_{G1} ON, V_{GN} OFF→C_{GS}, C_{GD}, (n+1)*C_{DS}
V_{G1} OFF, V_{GN} ON→n*C_{GS}, n*C_{GD}, (n+1)*C_{DS}

By the disclosed approach, the device input capacitances can be modified during operation by means of selecting one of the two different gate terminals 111, 112 or both of them contemporarily.

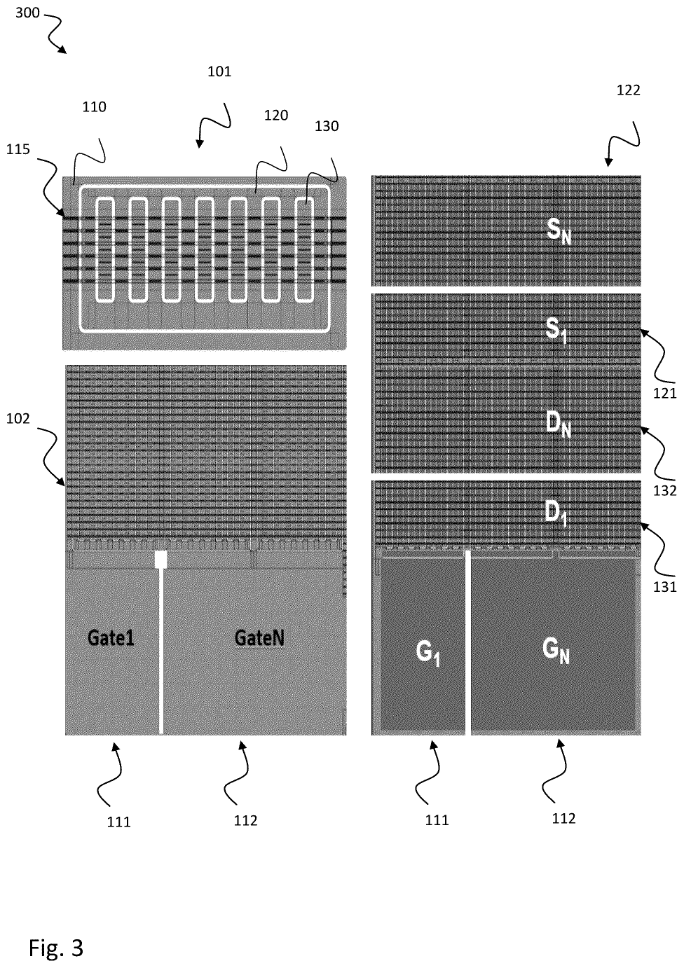

FIG. 3 shows an exemplary medium-voltage layout example 300 of the new GaN power transistor according to a second example.

The main difference with respect to the approach shown in FIG. 1 is represented by the fact that now also the source and drain terminals 121, 122, 131, 132 are split in two parts, respectively. Similarly, as for the two gate terminals 111, 112, also the two source/drain terminals 121, 122, 131, 132 connect two different portion of the device which have an area ratio N.

In the GaN power transistor 300 according to the second example as shown in FIG. 3, the source pad S is separated in a first source pad S1 and a second source pad SN; the drain pad D is separated in a first drain pad D1 and a second drain pad DN; the source metallization layer is separated in a first source metallization layer contacting the source regions 120 of the first portion of the unit cells 101 with the first source pad S1 and a second source metallization layer contacting the source regions 120 of the second portion of the unit cells 101 with the second source pad SN; and the drain metallization layer is separated in a first drain metallization layer contacting the drain regions 130 of the first portion of the unit cells 101 with the first drain pad D1 and a second drain metallization layer contacting the drain regions 130 of the second portion of the unit cells 101 with the second drain pad DN.

The first source pad S1 may form a first source terminal 121 of the GaN power transistor 300 for the first portion of the unit cells 101; the second source pad SN may form a second source terminal 122 of the GaN power transistor 300 for the second portion of the unit cells 101; the first drain pad D1 may form a first drain terminal 131 of the GaN power transistor 100 for the first portion of the unit cells 101; and the second drain pad DN may form a second drain terminal 132 of the GaN power transistor 300 for the second portion of the unit cells 101.

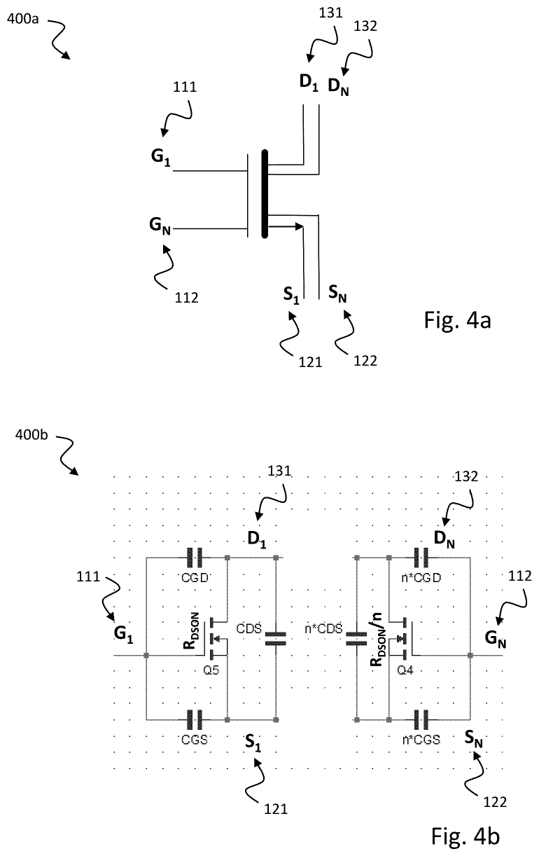

An input capacitance N*CGS between the second gate terminal 112, GN and the second source terminal 122, SN may be N times larger than an input capacitance CGS between the first gate terminal 111, G1 and the first source terminal 121, S1, e.g. as described below with respect to FIG. 4b. An input capacitance N*CGD between the second gate terminal 112, GN and the second drain terminal 132, DN may be N times larger than an input capacitance CGD between the first gate terminal 111, G1 and the first drain terminal 131, D1, e.g. as described below with respect to FIG. 4b.

Device capacitances of the GaN power transistor 300 can be modified during operation by selecting one or both of the first 111, G1 and second 112, GN gate terminals, e.g. as described below with respect to FIG. 4b.

A first device capacitance configuration: (N+1)*C_{GS}, (N+1)*C_{GD}, (N+1)*C_{DS} can be set by enabling both gate terminals 111, G₁, 112, G_{N}. A second device capacitance configuration: C_{GS}, C_{GD}, C_{DS} can be set by enabling the first gate terminal 111, G₁ and disabling the second gate terminal 112, G_{N}. A third device capacitance configuration: N*C_{GS}, N*C_{GD}, N*C_{DS} can be set by disabling the first gate terminal 111, G₁ and enabling the second gate terminal 112, G_{N}, e.g. as described below with respect to FIG. 4b.

FIG. 4a shows a transistor symbol 400a of the new GaN power transistor according to the second example. The transistor can be represented by a multi terminals device, where S1 and SN represent the two source terminals 121, 122; D1 and DN represents the two drain terminals 131, 132 and G1 and GN represent, respectively, the two gate terminals 111, 112.

FIG. 4b shows a circuit diagram 400b illustrating an equivalent circuit of the new GaN power transistor according to the second example.

In the circuit diagram 400b, the first gate terminal 111 is connected via capacitance CGD with first drain terminal 131 and via capacitance CGS with first source terminal 121. The second gate terminal 112 is connected via capacitance N*CGD with second drain terminal 132 and via capacitance N*CGS with second source terminal 122. The first Source terminal 121 is connected via parallel connection of transistor Q5 and capacitance CDS to first drain terminal 131. The second Source terminal 122 is connected via parallel connection of transistor Q4 and capacitance N*CDS to second drain terminal 132.

Different gate terminals 111, 112 can be selected during device operation and device performance can be tuned as follows:
V_{G1} ON, V_{GN} ON→(n+1)*C_{GS}, (n+1)*C_{GD}, (n+1)*C_{DS}
V_{G1} ON, V_{GN} OFF→C_{GS}, C_{GD}, C_{DS}
V_{G1} OFF, V_{GN} ON→n*C_{GS}, n*C_{GD}, n*C_{DS}

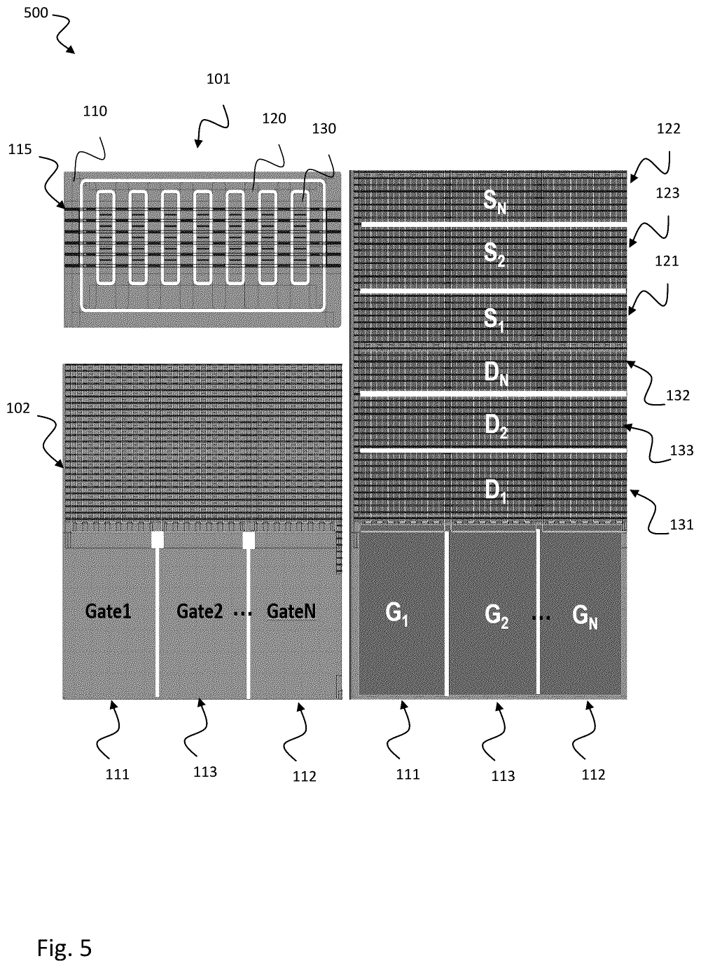

FIG. 5 shows an exemplary medium-voltage layout example 500 of the new GaN power transistor according to a third example.

The main difference with respect to the approach shown in FIGS. 1 and 3 is represented by the fact that now in the disclosed layout 500 for a medium-voltage GaN power device, gate 111, 112, 113, source 121, 122, 123 and drain 131, 132, 133 terminals are split in multiple portions (1, . . . , N) that correspond to different area of the device and with different sizes.

In the GaN power transistor 500 according to the third example as shown in FIG. 5, the source pad S is separated in multiple source pads S1, S2, SN; the drain pad D is separated in multiple drain pads D1, D2, DN; the first and the second gate pad G1, GN are separated in multiple gate pads G1, G2, GN. The source metallization layer is separated in multiple source metallization layers, each source metallization layer contacting the source region 120 of a respective portion of the unit cells 101 with a respective source pad of the multiple source pads S1, S2, SN. The drain metallization layer is separated in multiple drain metallization layers, each drain metallization layer contacting the drain region 130 of a respective portion of the unit cells 101 with a respective drain pad of the multiple drain pads D1, D2, DN. The gate metallization layer is separated in multiple gate metallization layers, each gate metallization layer contacting the gate region 110 of a respective portion of the unit cells 101 with a respective gate pad of the multiple gate pads G1, G2, GN.

The respective portions of the unit cells 101 may have different ratios in terms of area.

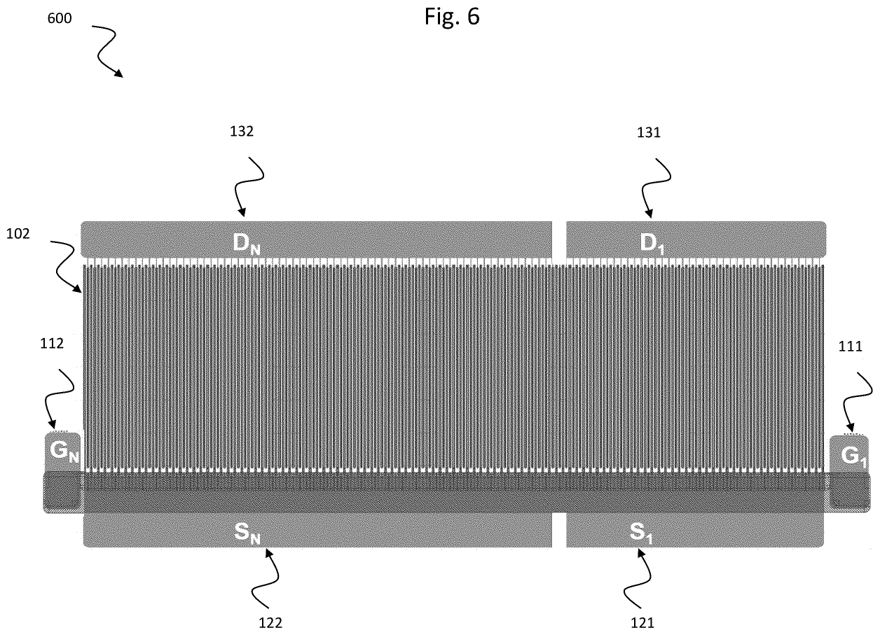

FIG. 6 shows an exemplary high-voltage (i.e. about 600-650V) layout example 600 of the new GaN power transistor according to the disclosure.

Main difference with respect to the layouts represented in FIGS. 1, 3 and 5 is represented by the fact that the different GaN fingers are all connected to large source 121, 122 and drain 131, 132 terminals which reside at the two extremes of each GaN finger. Gate connection 111, 112 is done on the side of the layout 600. This kind of approach is called bond over non-active because the drain and source pad lie outside the active area of the device. The main advantage of this approach is a simpler back-end-of-line (BEOL) scheme because the non-crossing structure of the layout 600 allows to relax the requirements of maximum voltage capability of the dielectric layers in the BEOL. Moreover, the large pads outside the active area allow to simplify the bonding scheme and to reduce the risks of cracks and, possible reliability issues. Drawback is, inevitably, worse area utilization and consequent increased cost per chip.

In particular, FIG. 6 shows a possible GaN HV layout 600, where gate 111, 112, source 121, 122 and drain 131, 132 are split into two parts, each of them connecting two different portion of the device that have an area ratio of N.

Similar alternative examples to the one previously discussed for the medium-voltage case (see FIGS. 1 to 5) can also be applied to the high-voltage design and similar considerations on the overall performance and equivalent circuits are one-to-one transferrable.

In a basic version, such a GaN power transistor 600 comprises: a source pad S; a drain pad D; a first and a second gate pad G1, GN; a plurality of unit cells 101 each unit cell comprising a source region 120, a drain region 130 and a gate region 110 as described above with respect to FIG. 1; a source metallization layer contacting the source regions 120 of the plurality of unit cells 101 with the source pad S; a drain metallization layer 115 contacting the drain regions 130 of the plurality of unit cells 101 with the drain pad D; a first gate metallization layer contacting the gate region 110 of a first portion of the unit cells 101 with the first gate pad G1; and a second gate metallization layer contacting the gate region 110 of a second portion of the unit cells 101 with the second gate pad GN, as described above with respect to FIG. 1.

The source pad S and the drain pad D (or the multiple source pads S1, SN and the multiple drain pads D1, DN) may be arranged outside of an active area of the GaN power transistor formed by the plurality of unit cells 101.

The source metallization layer may be arranged side by side with the drain metallization layer in order to connect the source regions 120 of the plurality of unit cells 101 (see FIG. 1) with the source pad S. The drain metallization layer may be arranged side by side with the source metallization layer in order to connect the drain regions 130 of the plurality of unit cells 101 (see FIG. 1) with the drain pad D.

Source metallization layer and drain metallization layer may be arranged side by side. This means, there are no crossings between both layers.

It understands that the structures according to the second and third example of the new GaN power transistor as shown in FIGS. 3 and 5 can be similarly implemented by the high-voltage layout example 600 of the new GaN power transistor as illustrated in FIG. 6.

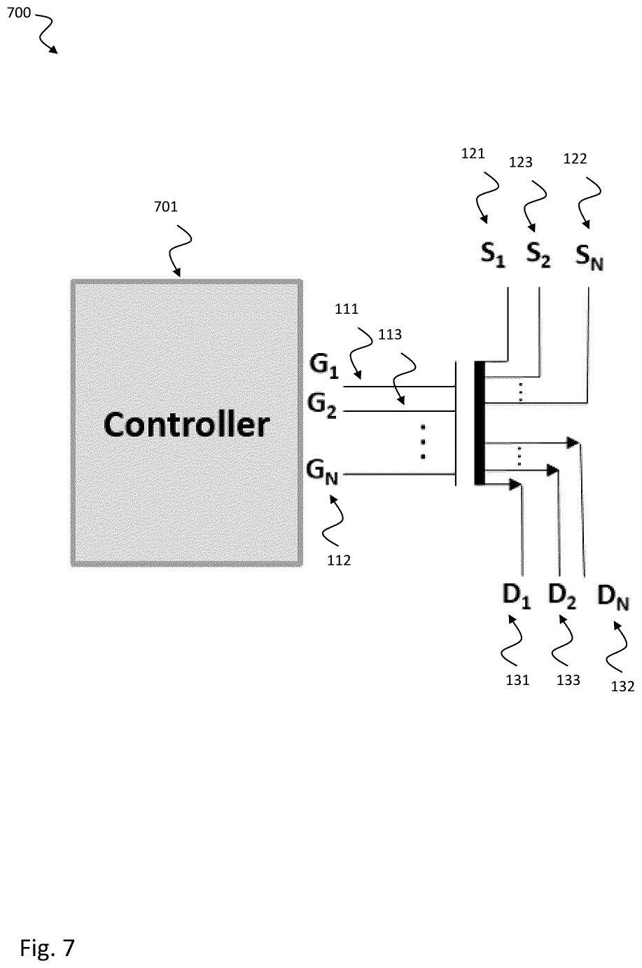

FIG. 7 shows a schematic diagram of a multi-terminal GaN power device 700 according to the disclosure. The multi-terminal GaN power device 700 comprises multiple source terminals 121, 122, 123, multiple drain terminal 131, 132, 133 and multiple gate terminals 111, 112, 113. A controller 701 can control the multi-terminal GaN power device 700 via multiple gate terminals 111, 112, 113.

The terminals can be alternatively selected during device operation in such a way to tailor the transistor performance during operation.

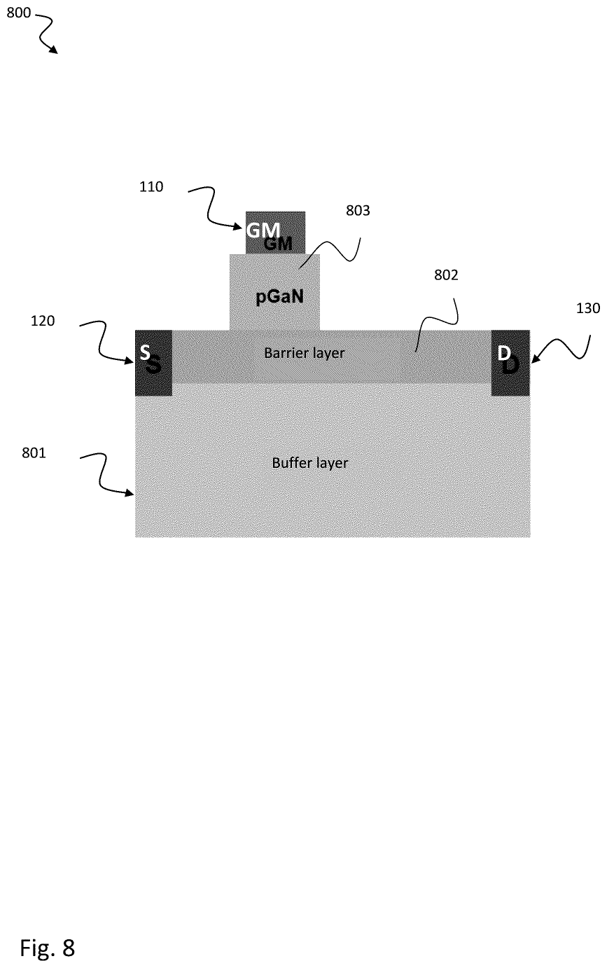

FIG. 8 shows a schematic diagram illustrating an exemplary structure of the new GaN power transistor 800 according to the disclosure. This structure 800 may represent a unit cell 101 as described above with respect to FIGS. 1, 3 and 5. The structure 800 comprises a buffer layer 801; a barrier layer 802 deposited on the buffer layer 801; and a p-type doped GaN layer 803 deposited on top of the barrier layer 802. The gate region 110 is formed on top of the p-type doped GaN layer 803. The source region 120 and the drain region 130 are formed laterally to the barrier layer 802.

In an alternative structure of the GaN power transistor 800, a passivation layer instead of the pGaN layer 803 may be deposited on top of the barrier layer 802.

The buffer layer 801 may comprise a GaN layer or an Aluminum Gallium Nitride (AlGaN) layer.

The barrier layer 802 may comprise an AlGaN layer.

The buffer layer 801 may be formed on at least one transition layer that may be formed on a Silicon substrate.

While a particular feature or aspect of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Also, the terms “exemplary”, “for example” and “e.g.” are merely meant as an example, rather than the best or optimal. The terms “coupled” and “connected”, along with derivatives may have been used. It should be understood that these terms may have been used to indicate that two elements cooperate or interact with each other regardless whether they are in direct physical or electrical contact, or they are not in direct contact with each other.

Although specific aspects have been illustrated and described herein, it will be appreciated by those of ordinary skill in the art that a variety of alternate and/or equivalent implementations may be substituted for the specific aspects shown and described without departing from the scope of the present disclosure. This application is intended to cover any adaptations or variations of the specific aspects discussed herein.

Although the elements in the following claims are recited in a particular sequence with corresponding labeling, unless the claim recitations otherwise imply a particular sequence for implementing some or all of those elements, those elements are not necessarily intended to be limited to being implemented in that particular sequence.

Many alternatives, modifications, and variations will be apparent to those skilled in the art in light of the above teachings. Of course, those skilled in the art readily recognize that there are numerous applications of the technology beyond those described herein. While the present technology has been described with reference to one or more particular embodiments, those skilled in the art recognize that many changes may be made thereto without departing from the scope of the present technology. It is therefore to be understood that within the scope of the appended claims and their equivalents, the technology may be practiced otherwise than as specifically described herein.

1. A Gallium Nitride (GaN) power transistor, comprising:
a source pad;
a drain pad;
a first gate pad;
a second gate pad;
a plurality of unit cells, wherein each unit cell, from the plurality of unit cells, includes a source region, a drain region, and a gate region;
a source metallization layer contacting the source regions, of the plurality of unit cells, with the source pad;
a drain metallization layer contacting the drain regions, of the plurality of unit cells, with the drain pad;
a first gate metallization layer contacting the gate region, of a first portion of the plurality of unit cells, with the first gate pad; and
a second gate metallization layer contacting the gate region, of a second portion of the unit cells, with the second gate pad.

2. The GaN power transistor according to claim 1,
wherein the first portion of the unit cells and the second portion of the unit cells include an area having a ratio of N.

3. The GaN power transistor according to claim 1, wherein
the source pad forms a common source terminal of the GaN power transistor for all unit cells;
the drain pad forms a common drain terminal of the GaN power transistor for all unit cells;
the first gate pad forms a first gate terminal of the GaN power transistor for the first portion of the plurality of unit cells; and
wherein the second gate pad forms a second gate terminal of the GaN power transistor for the second portion of the plurality of unit cells.

4. The GaN power transistor according to claim 3,
wherein an input capacitance N*C_{GS} between the second gate terminal and the source terminal is N times larger than an input capacitance C_{GS} between the first gate terminal and the source terminal; and
wherein an input capacitance N*C_{GD} between the second gate terminal and the drain terminal is N times larger than an input capacitance C_{GD} between the first gate terminal and the drain terminal.

5. The GaN power transistor according to claim 3,
wherein an output capacitance of the GaN power transistor is N+1 times a capacitance CDS between the drain terminal and the source terminal.

6. The GaN power transistor according to claim 3,
wherein input capacitances of the GaN power transistor are configured for modification during operation by selecting one or both of the first and second gate terminals.

7. The GaN power transistor according to claim 6, wherein
a first device capacitance configuration: (N+1)*C_{GS}, (N+1)*C_{GD}, (N+1)*C_{DS} is set by enabling the first and second gate terminals;
a second device capacitance configuration: C_{GS}, C_{GD}, (N+1)*C_{DS} is set by enabling the first gate terminal and disabling the second gate terminal; and
a third device capacitance configuration: N*C_{GS}, N*C_{GD}, (N+1)*C_{DS} is set by disabling the first gate terminal and enabling the second gate terminal.

8. The GaN power transistor according to claim 1, wherein
the source pad is separated in a first source pad and a second source pad;
the drain pad is separated in a first drain pad and a second drain pad;
the source metallization layer is separated in a first source metallization layer contacting the source regions of the first portion of the plurality of unit cells with the first source pad and a second source metallization layer contacting the source regions of the second portion of the plurality of unit cells with the second source pad; and
the drain metallization layer is separated in a first drain metallization layer contacting the drain regions of the first portion of the plurality of unit cells with the first drain pad and a second drain metallization layer contacting the drain regions of the second portion of the plurality of unit cells with the second drain pad.

9. The GaN power transistor according to claim 8, wherein
the first source pad forms a first source terminal of the GaN power transistor for the first portion of the unit cells;
the second source pad forms a second source terminal of the GaN power transistor for the second portion of the unit cells;
the first drain pad forms a first drain terminal of the GaN power transistor for the first portion of the unit cells; and
the second drain pad forms a second drain terminal of the GaN power transistor for the second portion of the unit cells.

10. The GaN power transistor according to claim 9, wherein
an input capacitance N*C_{GS} between the second gate terminal and the second source terminal is N times larger than an input capacitance C_{GS} between the first gate terminal and the first source terminal; and
an input capacitance N*C_{GD} between the second gate terminal and the second drain terminal is N times larger than an input capacitance C_{GD} between the first gate terminal and the first drain terminal.

11. The GaN power transistor according to claim 8,
wherein device capacitances of the GaN power transistor are configured to be modified during operation by selecting one or both of the first and second gate terminals.

12. The GaN power transistor according to claim 11, wherein
a first device capacitance configuration: (N+1)*C_{GS}, (N+1)*C_{GD}, (N+1)*C_{DS} is configured to be set by enabling both gate terminals (111, G₁, 112, G_{N});
a second device capacitance configuration: C_{GS}, C_{GD}, C_{DS} is configured to be set by enabling the first gate terminal and disabling the second gate terminal; and
a third device capacitance configuration: N*C_{GS}, N*C_{GD}, N*C_{DS} is configured to be set by disabling the first gate terminal and enabling the second gate terminal.

13. The GaN power transistor according to claim 1, wherein
the source pad is separated in multiple source pads;
the drain pad is separated in multiple drain pads;
the first and the second gate pads are separated in multiple gate pads;
the source metallization layer is separated in multiple source metallization layers, wherein each source metallization layer contacts the source region of a respective portion of the plurality of unit cells with a respective source pad of the multiple source pads;
the drain metallization layer is separated in multiple drain metallization layers, wherein each drain metallization layer contacts the drain region of a respective portion of the plurality of unit cells with a respective drain pad of the multiple drain pads; and
the gate metallization layer is separated in multiple gate metallization layers, wherein each gate metallization layer contacting the gate region of a respective portion of the plurality of unit cells with a respective gate pad of the multiple gate pads.

14. The GaN power transistor according to claim 13,
wherein the respective portions of the plurality of unit cells include areas having different ratios.

15. The GaN power transistor according to claim 1, wherein each unit cell comprises:
a buffer layer;
a barrier layer deposited on the buffer layer; and
a p-type doped GaN layer deposited on top of the barrier layer,
wherein the gate region of the unit cell is formed on top of the p-type doped GaN layer, and the source region and the drain region of the unit cell are formed laterally to the barrier layer.

16. The GaN power transistor according to claim 1, wherein each unit cell comprises:
a buffer layer;
a barrier layer deposited on the buffer layer; and
a passivation layer deposited on top of the barrier layer,
wherein the gate region of the unit cell is formed on top of the passivation layer, and the source region and the drain region of the unit cell are formed laterally to the barrier layer.

17. The GaN power transistor according to claim 1, wherein
the source metallization layer comprises at least one crossing with the drain metallization layer in order to connect the source regions, of the plurality of unit cells, with the source pad; and
the drain metallization layer comprises at least one crossing with the source metallization layer in order to connect the drain regions of the plurality of unit cells with the drain pad.

18. The GaN power transistor according claim 17,
wherein the source pad and the drain pad are arranged on top of an active area of the GaN power transistor formed by the plurality of unit cells.

19. The GaN power transistor according to claim 1,
wherein the source pad and the drain pad are arranged outside of an active area of the GaN power transistor formed by the plurality of unit cells.

20. The GaN power transistor according to claim 19,
wherein the source metallization layer is arranged side by side with the drain metallization layer in order to connect the source regions of the plurality of unit cells with the source pad; and
wherein the drain metallization layer is arranged side by side with the source metallization layer in order to connect the drain regions of the plurality of unit cells with the drain pad.
